(19) United States
(12) Patent Application Publication
(10) Pub. No.: US 2014/0001880 A1
(43) Pub. Date: Jan. 2, 2014

(54) DEVICE FOR TRANSMITTING ELECTRIC POWER AND/OR ELECTRIC SIGNALS FROM A STATIONARY WALL TO A WING FIXED TO THE WALL

(71) Applicants: Tibor Herglotz, Kreuzau (DE); Ingo Steinfeld, Langenfeld (DE)

(72) Inventors: Tibor Herglotz, Kreuzau (DE); Ingo Steinfeld, Langenfeld (DE)

(73) Assignee: DR. HAHN GMBH & CO. KG, Moenchengladbach-Wickrath (DE)

(21) Appl. No.: 14/005,273

(22) PCT Filed: Dec. 23, 2011
(86) PCT No.: PCT/EP2011/073988

§ 371 Date: Sep. 16, 2013

(30) Foreign Application Priority Data
Mar. 17, 2011 (DE) 20 2011 000 613.1

(51) Int. Cl. H05K 9/00; H01F 38/14

(52) U.S. Cl. CPC H05K 9/0007; H01F 38/14
USPC 307/104

(57) ABSTRACT

A device for transmitting at least one of electrical power and electrical signals from a wall to a wing fixed to the wall in an articulated manner about a hinge axis includes a transmitter for at least one of power and signals and a shielding configured to shield the transmitter from an external magnetic field. The transmitter operates in a contactless manner.

### CROSS REFERENCE TO PRIOR APPLICATIONS

This application is a U.S. National Phase application under 35 U.S.C. § 371 of International Application No. PCT/EP2011/073988, filed on Dec. 23, 2011 and which claims benefit to German Patent Application No. 20 2011 000 613.1, filed on Mar. 17, 2011. The International Application was published in German on Sep. 20, 2012 as WO 2012/123040 A1 under PCT Article 21(2).

### FIELD

The present invention relates to a device for transmitting electrical power and/or electrical signals from a stationary wall to a wing fixed to a wall in an articulated manner about a hinge axis, with a power and/or signal transmitter that operates in a contactless manner.

Belts that are used to connect a wing in a hinged manner to a wall are known. They have proven themselves in a variety of different technical designs and are also used in doors for objects such as houses, businesses or even in escape doors.

Such doors increasingly have devices that improve safety or comfort and are operated by means of electrical power. These devices can comprise sensors, for example, glass breakage sensors that send signals to a device on the wall, for example, a burglar alarm control panel.

To transmit power and/or signals, these devices are therefore usually connected to an external power source via flexible cables.

These cable connections considerably impair the visual appearance and can become lodged between the wing and the wall, which can lead to damage or even destruction of the cable.

Hinges with power and/or signal transmitters operating in a contactless manner are described in, for example, DE 39 15 812 A1 and DE 10 2004 017 341 A1. DE 39 15 812 A1 describes an embodiment of, concentrically arranged coils or as a cylindrical capacitor. DE 10 2004 017 341 A1 describes an embodiment where the power and/or signal transmitter operating in a contactless manner comprises a first coil arranged in a frame belt part and a second coil arranged in a wing belt part. The magnetic coupling of the two coils, which are spaced apart from one another in the direction of the hinge axis, is achieved with a hinge bolt.

While it is in principle possible with the aforementioned known devices to provide contactless power transmission from a stationary frame to a wing arranged in a pivoted manner on the frame, experiments have shown that the power transmission is prone to interference.

### SUMMARY

An aspect of sent invention is to improve the operational reliability of the above described devices.

In an embodiment, the present invention provides a device for transmitting at least one of electrical power and electrical signals from a wall to a wing fixed to the wall in an articulated manner about a hinge axis which includes a transmitter for at least one of power and signals and a shielding configured to shield the transmitter from an external magnetic field. The transmitter operates in a contactless manner.

### BRIEF DESCRIPTION OF THE DRAWINGS

The present invention is described in greater detail below on the basis of embodiments and of the drawings in which:

FIG. 1 shows (schematically and in partial section) an embodiment of a device according to the present invention with a first possible design of the housing parts and with wall and wing parts that have not yet been completely joined together;

FIG. 2 shows the first and second housing parts with the first and second coil arrangements from FIG. 1 located therein in a longitudinal section through the hinge axis;

FIG. 3 schematically shows a view corresponding to FIG. 2 of an embodiment of a design of the housing parts of the shield;

FIG. 4 schematically shows a view corresponding to FIG. 2 of an embodiment of a design of the housing parts of the shield;

FIG. 5 schematically shows a view corresponding to FIG. 2 of an embodiment of a design of the housing parts of the shield;

FIG. 6 shows (schematically and in partial section) the first and second housing parts with first and second coil arrangements located therein in a longitudinal section through the hinge axis of an embodiment of the device according to the present invention, with a still-existing gap between the two housing parts, and

FIG. 7 shows the embodiment illustrated in FIG. 6 but with joined first and second housing parts.

### DETAILED DESCRIPTION

The device according to the present invention for transmitting electrical power and/or electrical signals from a stationary wall to a wing fixed to a wall in an articulated manner about a hinge axis, said wing comprising a power and/or signal transmitter that operates in a contactless manner, has means for shielding the power and/or signal transmitter from external magnetic fields. It has surprisingly been shown that external magnetic fields such as those produced by many pieces of equipment can influence power and/or signal transmitters that operate in a contactless manner to such an extent that even the power transmission is negatively impacted to a substantial extent.

The means for shielding the power and/or signal transmitter from external magnetic fields can in principal be embodied in any manner that leads to a reduction of the magnetic field intensity acting as a result of external magnetic fields on the site of the power and/or signal transmitter. The shielding means can, however, be manufactured especially effectively and simply if they have a housing that encloses the power and/or signal transmitter at least in part and comprises a soft magnetic material. The term “comprising soft magnetic materials” also includes a housing that is comprised completely of the soft magnetic material. The housing need not necessary be designed as a separate component; it is also possible to embody the parts of the device in which the power and/or signal transmitter is arranged out of a suitable material. The housing can, for example, be comprised of a plastic in which particles of a soft magnetic material are embedded.

Examples of soft magnetic materials include ferromagnetic materials of high permeability and low remanence, since they also act against the penetration of low-frequency magnetic fields or constant fields. So-called mu-metal is named here for the sake of example.

If these soft magnetic materials are also electrically conductive, they then simultaneously have a shielding effect on electrical fields.

In an embodiment of the present invention, the device can, for example, be designed similarly to a conventional hinge and comprises, accordingly, a wall part fixed on the wall and a wing part that can be swiveled thereto about the hinge axis. What is meant here by “similarly to a hinge” is that this device need not be assigned a convention hinge function, i.e., the mechanical holding of the wing, but can rather also be provided in addition to conventional hinges and be used exclusively for transmitting power and/or signals.

In an embodiment of the present invention, in this device, a first part of the power and/or signal transmitter can, for example, be arranged in the wall part and a second part of the power and/or signal transmitter can be arranged in the wing part. Both the wall part and the wing part are then weakened to the same extent by the first and second parts of the power and/or signal transmitter, particularly only slightly less than if both parts of the power and/or signal transmitter were provided in one of the wall or wing parts.

In an embodiment of the present invention, the housing for shielding from external magnetic fields can, for example, comprise a first, for example, a cup-shaped housing part enclosing the first part of the power and/or signal transmitter and a second, for example, a cup-shaped housing part enclosing the second part of the power and/or signal transmitter, wherein open sides of the first and second housing parts face one another. If the housing parts are embodied in the shape of cups, then the bottoms can be integrally shaped or also be embodied as separate components.

To enable the wing part to swivel relative to the wall part about the hinge axis, either at least one of the housing parts must be pivoted in the wall part or wing part or, for example, the first and second housing parts are arranged in an articulated manner with respect to each other about a hinge axis as a result of a division of the parts at a separation plane running perpendicular to the hinge axis.

In an embodiment, the first and second housing parts are provided so that they overlap in the direction of the swivel axis in order to prevent magnetic field lines from penetrating between the housing parts into the housing in an unshielded manner. The housing parts are cylindrical for this purpose. For example, they have such different diameters that one housing part works together with the other housing part in the manner of a telescope.

In an embodiment of the present invention, the protective shells of the first and second housing parts can, for example, have about the same diameter. Their mutually facing edges are then contoured in complementary fashion to one another such that they engage in the area of the separating plane. For this purpose, the edges can be inversely chamfered or provided, for example, with an annular groove/annular spring characteristic having any configuration.

In an embodiment of the device according to the present invention, the first part of the power and/or signal transmitter is a first coil arrangement provided in the wall part, and the second part of the power and/or signal transmitter is a second coil arrangement provided in the wing part.

If the parts of the power and/or signal transmitter are embodied as coil arrangements, the quality of the electromagnetic coupling depends substantially on the distance between the two parts of the power and/or signal transmitter. A small air gap on the order of one millimeter or less can negatively impact the coupling quality such that electrical power for which the parts themselves are designed can no longer be transmitted. The dissipation occurring during transmission can also increase to an undesirable extent. In an embodiment of the device according to the present invention, the first part of the power and/or signal transmitter is therefore arranged in the first housing part and/or the second part of the power and/or signal transmitter is arranged in the second housing part such that they can be moved in the direction of the hinge axis. Due to this movability, it can be provided that, even with manufacturing tolerances, the two parts of the power and/or signal transmitter have minimum spacing between one another and, in the case of coils, their coil bodies, coil cores and/or windings at least nearly abut each other when the two housing parts of the shield are in their correct installed position. Another consequence of this movable arrangement is that wear caused, for example, by relative movements of the two housing parts does not result in the two parts of the power and/or signal transmitter abutting one another with increasing force if at least one of the housing parts is spring-loaded in the direction of the hinge axis, which could lead to the damaging or even destruction of the power and/or signal transmitter.

In an embodiment of the present invention, the first part of the power and/or signal transmitter can, for example, be supported via a spring- or rubber-elastic element in the first housing part and/or the second part of the power and/or signal transmitter can, for example, be supported via a spring- or rubber-elastic element on a wall facing the respective open side. The wall can, for example, be a bottom of the respective housing part. This spring- or rubber-elastic element is arranged between the bottom of the respective housing part and the respective part of the power and/or signal transmitter. This element can comprise, for example, a short coil spring, a disc spring or a layer of a rubber-elastic material.

In an embodiment of the present invention, the first part of the power and/or signal transmitter, with the exception of the side facing toward the second part of the power and/or signal transmitter and/or the second part of the power and/or signal transmitter, with the exception of the side facing toward the power and/or signal transmitter, can, for example, be covered at least in part by an elastic, for example, a rubber-elastic, pliable material layer that abuts an opposing side of the first or second housing part, respectively. By virtue of this measure, not only is a movability of one or both parts of the power and/or signal transmitter realized in the respectively associated housing part in the direction of the hinge axis, but a movability in directions transverse to the hinge axis is also achieved. An effect of this “floating” mounting of one or both parts of the power and/or signal transmitter in the respective housing part of the shield is that manufacturing tolerances that cause the two facing sides of the parts of the power and/or signal transmitter to initially not lie flat against one another but rather at points or along lines are also compensated for. The floating mount accordingly causes the two parts of the power and/or signal transmitter to align automatically with one another.

If an exact centering, i.e., an exact positioning perpendicular to the hinge axis, is required for optimal coupling, then the two parts of the power and/or signal transmitter can have centering means on the sides facing one another, for example, a centering extension on one side that engages in a centering recess provided on the other side.

The first and second coils can then be traversed by a hinge bolt defining the hinge axis which can then, at the same time, improve the magnetic coupling between the first and second spools.

In order for the hinge bolt to work together mechanically with the wall part and the wing part for the purpose of increasing the stability even outside of the first and second coil arrangements, and in order to facilitate the assembly of the device according to the present invention, the first and/or the second housing part can, for example, comprises an opening that is suited to the passing-through of the hinge bolt.

The opening and the hinge bolt can then be dimensioned such that the edge of the opening lies close to the circumferential surface of the hinge bolt. What is meant here by “close” is an annular gap between the edge of the opening and the circumferential surface of the hinge bolt that is as small as possible and does not exceed a gap width of a few millimeters, for example, a few tenths of a millimeter.

If the housing parts are embodied, for example, as separate components from the hinge and wing parts, then they can, for example, be non-positively, adhesively or positively connected to the coil arrangements into assemblies. This measure facilitates joining with the hinge or wing part.

So that the housing parts are arranged as closely as possible in order to prevent a continuous separating gap even after final mounting and a multiple swiveling of the wing about the hinge axis, and so that any manufacturing tolerances can be compensated for, pressing means can, for example, be provided with which the housing parts can be pressed together. For this purpose, the wall and/or the wing parts can be embodied such that at least one of the two housing parts can be moved in the respective wall or wing part in the direction of the hinge axis S. A pressure spring that acts from the outside onto the bottom of at least one housing part can then, for example, be used to press onto the respective other housing part.

The invention will now be explained in further detail on the basis of the drawings.

The embodiments of a device according to the present invention, designated as a whole with 100, for transmitting electrical power and/or electrical signals from a stationary wall W to a wing F fixed in an articulated manner about a hinge axis S comprises a power and/or signal transmitter 1 that operates in a contactless manner. In the depicted embodiment, it comprises a first coil arrangement 2 on the wall side and a second coil arrangement 3 on the wing side. The coil arrangements 2, 3 are arranged concentrically to the hinge axis S. The coil arrangements 2, 3 comprise first and second coil windings 4, 5 that are enclosed by first and second coil housings 6 and 7. The coil housings comprise soft magnetic material, for example ferrite, and are used to improve the inductive coupling of the first and second coil arrangements 2, 3.

The coil arrangements 2, 3, are traversed by a hinge bolt 8 defining the hinge axis S, which hinge bolt 8 protrudes with its lower end into a hinge part 9 of a wall part 10 fixed on the wall W and with its upper end into a hinge part 11 of a wing part 12 fixed on a wing F. The upper end of the hinge bolt 8 is supported in a bushing 13. The hinge bolt 8 is fixed in the direction of the hinge axis S with the aid of a stud screw (not shown in the drawing) protruding into an annular groove 15.

Approximately over the length over which the two coil arrangements 2, 3 extend, the hinge bolt 8 comprises a recess 16 in which the sleeve 17 made of a soft magnetic material, particularly ferrite material, is embedded. It serves, in turn, to improve the inductive coupling of the first and second coil arrangements 2, 3.

The device according to the present invention 100 further comprises means for shielding 18 of the power and/or signal transmitter 1 from external magnetic fields. They comprise a housing 19 which is comprised of a soft magnetic material, particularly a ferromagnetic material, for example, mu-metal. The housing 19 is divided on a plane E running perpendicular to the hinge axis S into the first housing part 20 and the second housing part 21.

The two housing parts 20, 21 are embodied in a somewhat cup shape and in a single piece in the depicted embodiments. Their bottoms 22, 23 have openings 24, 25 whose diameter only slightly exceeds the outer diameter of the hinge bolt 8 and the sleeve 17. It is, however, also conceivable, independently of the remaining design of the device, to do without bottoms 22, 23 or to embody them as separate components.

The soft magnetic materials 26, 27 of the housing parts 20, 21, made of mu-metal, for example, are covered by an electrically insulating plastic material 30 with the exception of the edges 28, 29 facing the plane E.

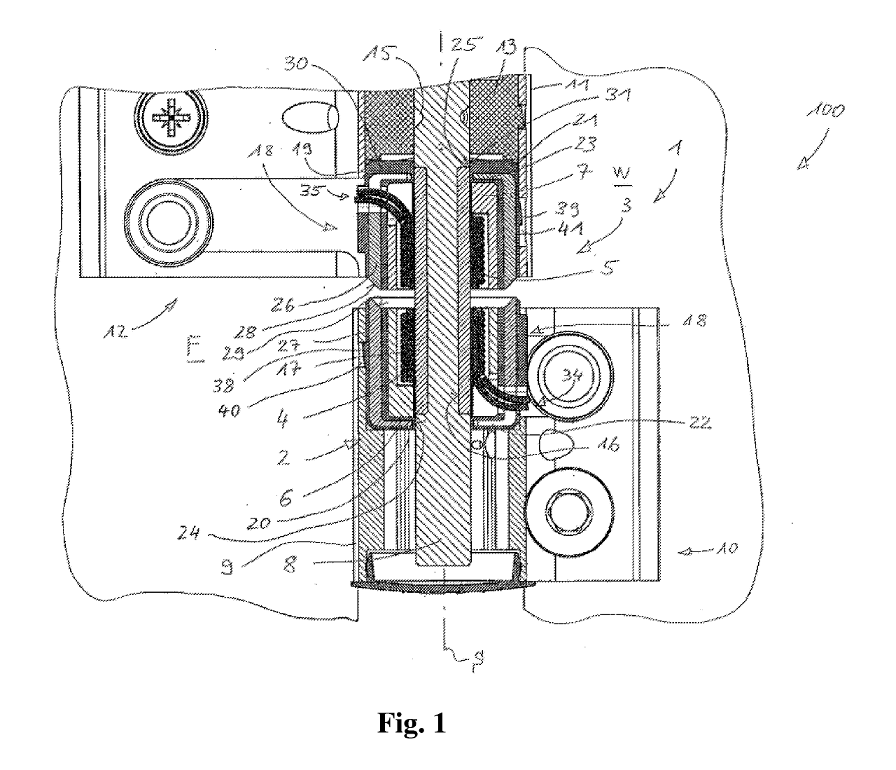

In the illustration according to FIG. 1, the two housing parts 20, 21 are not yet completely pushed together so that the two edges 28, 29 are still spaced apart from one another in the direction of the hinge axis S.

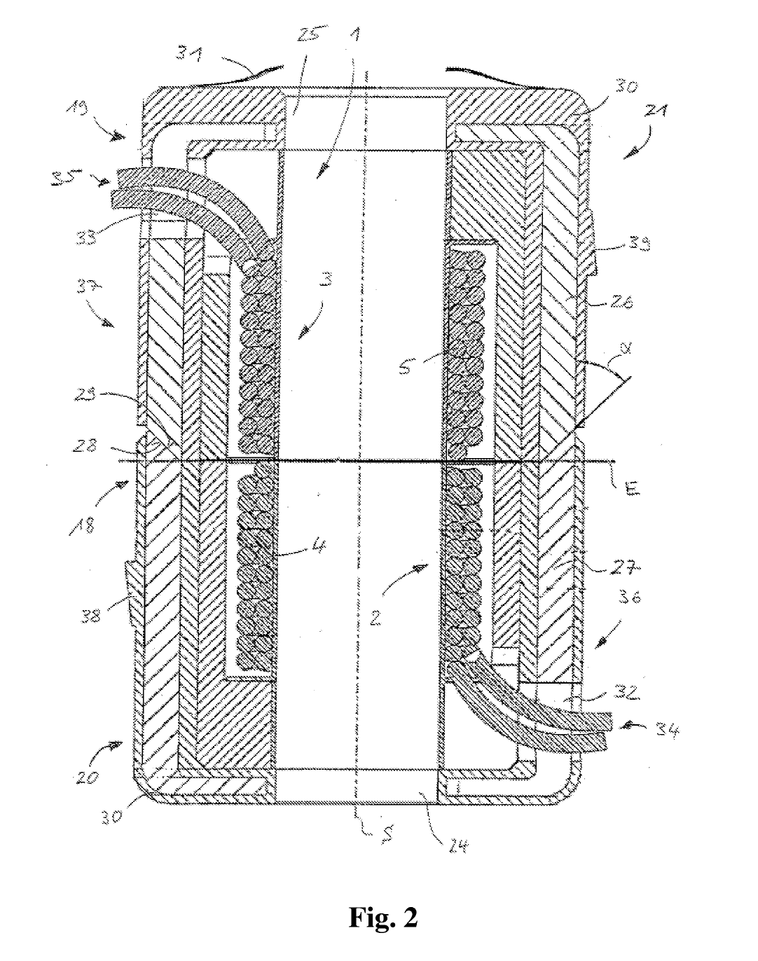

As is particularly visible in FIG. 2, the edges 28, 29 abut each other completely after the housing parts 20, 21 are completely joined together. Since the housing edges 28, 29 are chamfered in complementary fashion at an angle α of 45° to the plane E, the edges 28, 29 overlap in the direction of the hinge axis S, as a result of which the shielding against external magnetic fields achieved with the housing 19 is improved compared to a non-overlapping design with a gap. In order to provide that the housing parts 20, 21 are in the tightly adjoining position shown in FIG. 2 even in the case of manufacturing tolerances, in other words: in order to compensate for manufacturing tolerances, a compression spring arrangement 31 is provided in the hinge part 11 of the wing part 12 which exerts a downward elastic force on the second housing part 21.

It is clear in FIG. 2 that the housing 19, with the exception of the openings 24, 25, which are necessary for the hinge bolt to pass through, nearly completely encloses the first and second coil arrangements 2, 3. Openings 32, 33 are merely present for connector cables 34, 35 of the first and second coil windings 4, 5, but they are mechanically sealed by means of an injectable material (not shown).

The coil arrangements 2, 3 are joined together with the housing parts 20, 21 into assemblies. In order to prevent them from rotating in the hinge parts 9, 11 about the hinge axis S, which could lead to the damaging or tearing of the connector cables 34, 35, locking catches 38, 39 that engage in locking recesses 40, 41 after insertion into the hinge parts 9, 11 are embodied in the plastic material 30. The upper locking recess 41 is (as shown in FIG. 1) longer in the direction of the hinge axis S than the locking catch 39 so that the abutment of the edges 28 and 29 is provided even in the event of manufacturing tolerances.

Through the inductive coupling of the first and second coil arrangements 2, 3, both electrical power and signals, both in the form of alternating current, can be transmitted from the wall W to the wing side and vice versa. The shield created with the aid of the housing 19 and nearly completely enclosing the first and second coil arrangements 2, 3 has the effect that external magnetic fields cannot influence the first and second coil arrangements 2, 3 or at least only with a reduced field intensity, as a result of which the proneness of the device 100 to interference is substantially reduced.

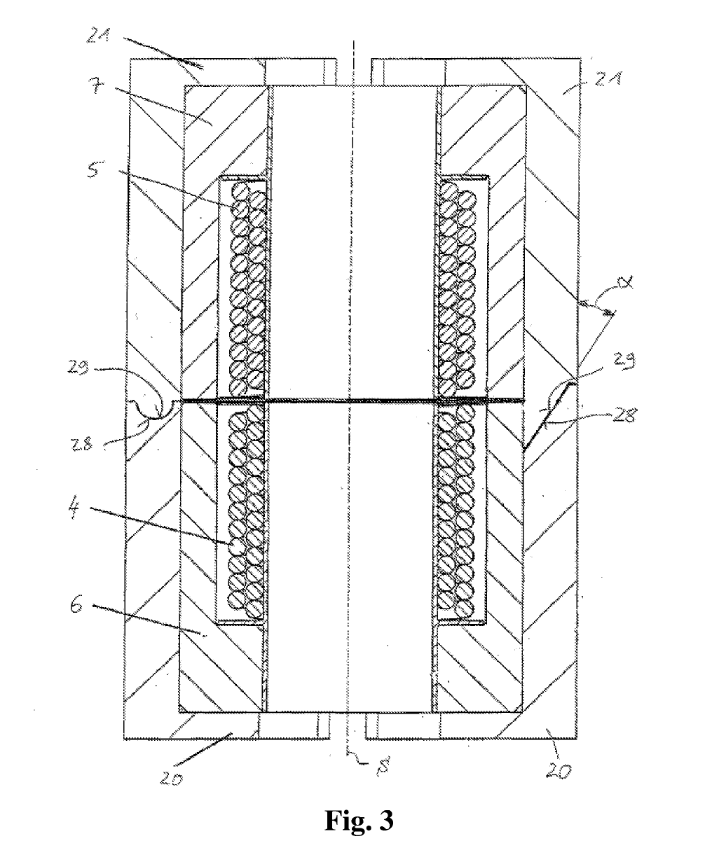

FIGS. 3 to 5 now show other embodiments of the assemblies 36, 37 in a view corresponding to that of FIG. 2, but shown is less detail. For instance, the connector cables for the coil arrangements 2, 3 as well as the configuration of the housing parts 20, 21 with soft magnetic material 26 that is coated with a plastic material, are not drawn in FIGS. 3 to 5 each show different configurations of the edges 28, 29 of the housing parts 20, 21 to the left and right of the hinge axis S. As will readily be understood, the variants depicted in each of these figures are not to be used in the same embodiment but rather only as alternatives.

In the variant shown to the left in FIG. 3, the edge of the second housing part 21 is convex instead of the complementary 45° chamfering of the edges 28, 29, and the edge 28 of the first housing part 20 is concave in complementary manner.

In the embodiment shown to the right in FIG. 3, a sharper angle to the hinge axis S is selected that in the embodiment according to FIG. 2.

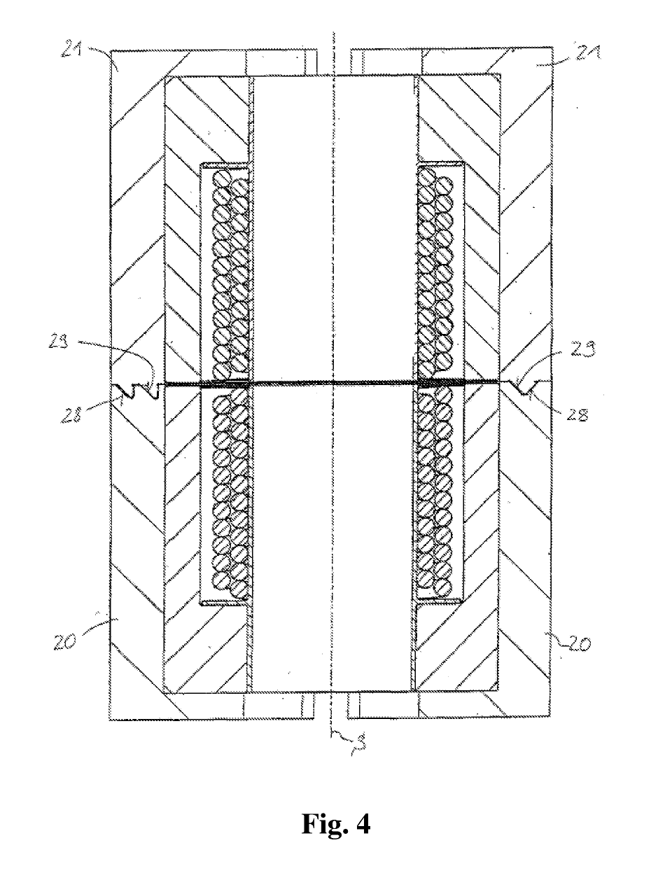

In the sample embodiment shown to the left in FIG. 4, two annular groves that are saw tooth-shaped in cross section are provided at the edge 28 of the first housing part 20, and complementary, all-around projections that are saber tooth shaped in cross section are provided accordingly at the upper edge 29 of the second housing part 21.

In the embodiment shown to the right in FIG. 4, an all-around groove is provided at the edge 28 of the first housing part 20 having approximately the cross section of an isosceles triangle, and a complementary projection is provided accordingly at the second housing part at its edge 29.

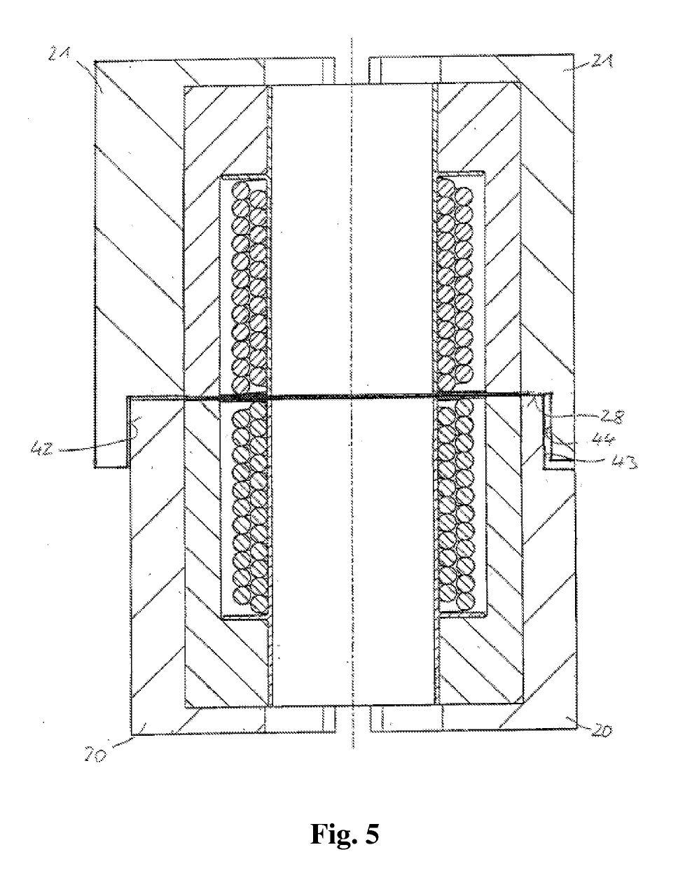

In FIG. 5, the first housing part 20 has a smaller outer diameter than the second housing part 21. However, the latter comprises a recess 42, so that the first housing part 21 is able to engage in the recess 42 in the manner of a telescope. In the embodiment shown to the right in FIG. 5, the first housing part 20 is reduced in diameter downward from the edge 28 over an area 43. The second housing part 21 has a complementary recess 44, so that the housing parts 20, 21 can in turn be pushed into one another over the length of the area 43 in the manner of a telescope.

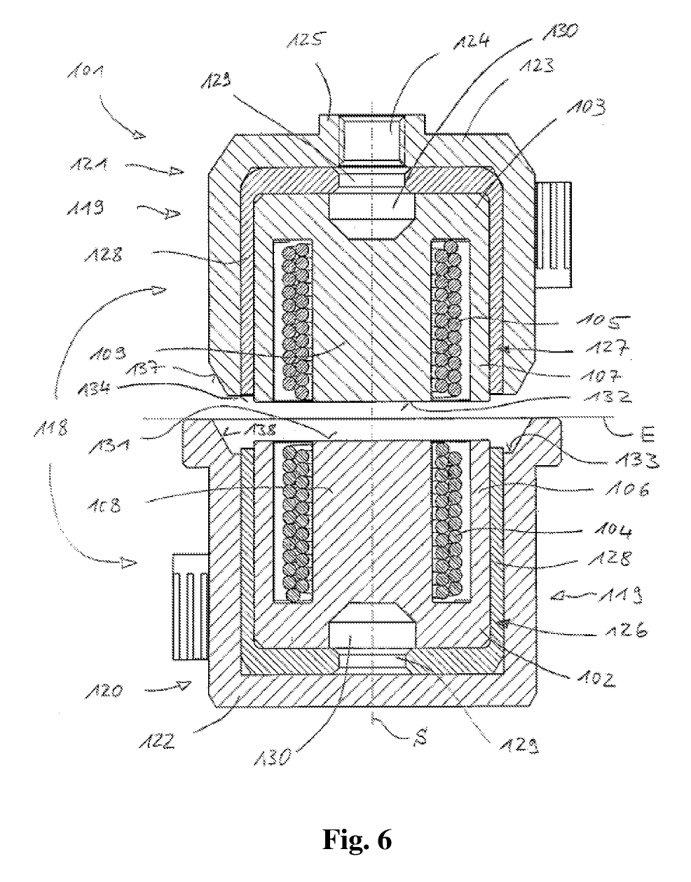

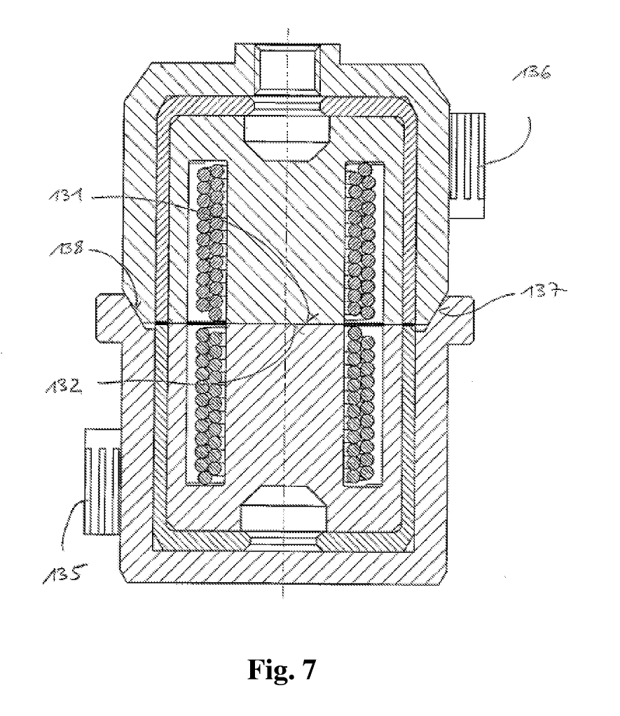

Another embodiment of a power and/or signal transmitter 101 is shown in FIGS. 6 and 7. In the depicted embodiment, it comprises, in turn, a wall-side first coil arrangement 102 and a wing-side second coil arrangement 103. The coil arrangements 102, 103 are arranged concentrically to the hinge axis S. The first and second coil arrangements 102, 103 comprise, in turn, first and second coil windings 104, 105 that are enclosed by first and second coil housings 106, 107. These coil housings are comprised of soft magnetic material, for example, ferrite, and serve to improve the inductive coupling of the first and second coil arrangements 102, 103.

Unlike the embodiments depicted in FIGS. 1 to 5, the coil arrangements 102, 103, 104 are not traversed by a hinge bolt defining the hinge axis S. Rather, the first and second coil housings 106, 107 comprise a first and second coil core 108, 109 around which the coil windings 104, 105 are arranged. The first and second coil cores 108, 109 are connected in a single piece to the respectively associated coil housing 106, 107 and are comprised of the same soft magnetic material.

In the case of the power and/or signal transmitter 101, means for shielding 118 from external magnetic fields are also provided. They comprise a housing 119 which comprises a soft magnetic, for example, a ferromagnetic material such as Mu-metal. The housing 119 is in turn divided at a plane E running perpendicular to the hinge axis S into a first housing part 120 and a second housing part 121.

The two housing parts 120, 121 are approximately cup-shaped and embodied in a single piece with the bottoms 122, 123. In the embodiments shown in FIGS. 6 and 7, the first bottom 122 of the first housing part 120 is continuous so that the first housing part 120 has approximately the shape of a closed pot, whereas the second bottom 123 of the second housing part 121 comprises a concentrically arranged threaded hole 124 that extends through a central, outwardly protruding projection 125. The threaded hole 124 is used for coupling to an adjusting device by means of which the second housing part 121 can be moved with respect to the first housing part 120 approximately in the direction of the hinge axis S.

Arranged in a “floating” manner, i.e., in an alternatively movable manner, the first coil housing 106 is arranged in the first housing part 120 and the second coil housing 107 in the second housing part 121. For this purpose, the coil housings 106, 107 and the respectively associated housing parts 120, 121 are embodied such that a first and second free space 127, 127 remain between the coil housings and the housing parts. The first and second free spaces 126, 127 are substantially filled with a rubber-elastic material 128, for example manufactured on the basis of silicon. The term “rubber-elastic” is intended to refer to a characteristic of the material that permits a reduction of its external volume in overcoming a restorative force.

Provided coaxially to the hinge axis S both in the rubber-elastic material 128 and in the first and second coil housings 106, 107 are openings 129 and holes 130 which permit the penetration or entry of a coupling component belonging to an adjusting device not shown in the drawing. In the embodiment shown in the drawing, only the movement of the second housing part 121 with the second coil arrangement 103 is provided for. The hole 130 and the opening 129 provided in the first coil housing 106 are therefore not necessary. They are present nonetheless, since structurally equivalent components are here being used.

As can be seen in FIG. 6, the mutually-facing front surfaces 131, 132 of the first coil housing and its core 108 as well as of the second coil housing 107 and its core 109 protrude over the mutually facing front surfaces 133, 134. If the two housing parts 120, 121 are now moved together, for example, with the aid of an adjusting device not shown in the drawing, such that the two front surfaces 133, 134 come to abut as is shown in FIG. 7, then the rubber-elastic material 128 is compressed to the extent that it abuts the bottoms 122, 123. The rubber-elastic restorative forces have the effect that the first and second front surfaces 131, 132 abut each other as best as possible. Insofar as necessary, as a result of the compressive forces prevailing between the first and second front surfaces 131, 132, the first and second coil housings 106, 107 are tipped under compression or expansion of the rubber-elastic material 128 within the free spaces 126, 127 to the extent necessary in order to compensate for a possible misalignment of the two front surfaces 131, 132.

In order to prevent the housing parts 120, 121 from rotating within the hinge parts not shown in FIGS. 6 and 7 about the hinge axis S, which could lead to the damaging or tearing of connector cables, a radially projecting anti-rotation lock 135, 136 is provided on each of the first and second housing parts 120, 121 that engages into a respective complementary recess provided in the respectively associated belt part.

As FIGS. 6 and 7 show, in the operational position shown in FIG. 7, chamfered housing part edges 137, 138 abut completely, and the front surfaces 131, 132 of the first and second coil housing 106, 107 lie flatly at the same time.

As will readily be understood, a number of other configurations are possible that have the same effect with respect to magnetic shielding as in those depicted here.

It should moreover be noted that the soft magnetic material 26, 27 can also comprise a plurality of different material components that can be distributed statistically in particle form and solidified in the housing shape or can even be arranged in a layered construction.

The present invention is not limited to embodiments described herein; reference should be had to the appended claims.

### List of Reference Symbols

100 device
1 power and/or signal transmitter
2 first coil arrangement
3 second coil arrangement
4 first coil winding
5 second coil winding
6 first coil housing
7 second coil housing
8 hinge bolt
9 hinge part
10 belt wall part
11 hinge part
12 wing part
13 bushing
15 annular groove
16 recess
17 sleeve
18 shielding means
19 housing
20 first housing part
21 second housing part
22 bottom
23 bottom
24 opening
25 opening
26 soft magnetic material
27 soft magnetic material
28 edge
29 edge
30 plastic material
31 compression spring arrangement
32 opening
33 opening
34 connector cable
35 connector cable
36 assembly
37 assembly
38 locking catch
39 locking catch
40 locking recess
41 locking recess
42 recess
43 area
44 recess
101 power and/or signal transmitter
102 first coil arrangement
103 second coil arrangement
104 first coil winding
105 second coil winding
106 first coil housing
107 second coil housing
108 first coil core
109 second coil core
118 shielding means
119 housing
120 first housing part
121 second housing part
122 first bottom
123 second bottom
124 threaded hole
125 projection
126 first free space
127 second free space
128 rubber-elastic material
129 openings
130 holes
131 first front surface
132 second front surface
133 front surface
134 front surface
135 anti-rotation lock
136 anti-rotation lock
137 housing part edge
138 housing part edge α angle
E plane
F wing
S hinge axis
W wall

What is claimed is:

1-15. (canceled)

16. A device for transmitting at least one of electrical power and electrical signals from a wall to a wing fixed to the wall in an articulated manner about a hinge axis, the device comprising:
a transmitter for at least one of power and signals; and
a shielding configured to shield the transmitter from an external magnetic field,
wherein the transmitter operates in a contactless manner.

17. The device as recited in claim 16, wherein the shielding comprises a housing configured to at least partially enclose the transmitter, the housing being comprised of a soft magnetic material.

18. The device as recited in claim 16, wherein the device further comprises a wall part configured to be fixable to the wall, and a wing part configured to pivot about the hinge axis.

19. The device as recited in claim 18, wherein the transmitter further comprises a first transmitter part and a second transmitter part, the first transmitter part being arranged in the wall part and the second transmitter part being arranged in the wing part.

20. The device as recited in claim 19, wherein the housing comprises a first housing part comprising a first open side and a second housing part comprising a second open side, the first housing part being configured to enclose the first transmitter part and the second housing part being configured to enclose the second transmitter part, the first open side and the second open side being arranged so as to face each other.

21. The device as recited in claim 20, wherein the first housing part and the second housing part are configured so as to swivel with respect to each another about the hinge axis.

22. The device as recited in claim 21, wherein the first housing part and the second housing part are configured to overlap in a direction of the hinge axis.

23. The device as recited in claim 22, wherein the first housing part further comprises a first shell and a first edge and the second housing part further comprises a second shell and a second edge, the first shell and the second shell each having a diameter which is essentially the same, the first edge and the second edge being configured so as to face each other and being contoured in a complimentary fashion with respect to each other.

24. The device as recited in claim 20, wherein at least one of the first transmitter part is arranged so as to be movable in the first housing part and the second transmitter part is arranged so as to be movable in the second housing part.

25. The device as recited in claim 24, wherein at least one of the first transmitter part in the first housing part and the second transmitter part in the second housing part is supported via a spring elastic element or via a rubber elastic element on a wall which is opposite to a respectively open side.

26. The device as recited in claim 25, wherein the support via the spring elastic element or via the rubber elastic element is on a bottom of the respective first housing part and second housing part.

27. The device as recited in claim 25, wherein at least one of the first transmitter part, with the exception of a side facing the second transmitter part, and the second transmitter part, with the exception of a side facing the first transmitter part, is at least partially coated with an elastic flexible material layer configured to abut an opposing side of the respective first housing part or second housing part.

28. The device as recited in claim 27, wherein the elastic flexible material layer is a rubber-elastic.

29. The device as recited in claim 19, wherein the first transmitter part comprises a first coil arrangement arranged in the wall part, and the second transmitter part comprises a second coil arrangement arranged in the wing part.

30. The device as recited in claim 29, further comprising a hinge bolt which defines the hinge axis, wherein the first coil arrangement and the second coil arrangement are each traversed by the hinge bolt.

31. The device as recited in claim 30, wherein the first coil arrangement and the second coil arrangement each comprise openings in a bottem, and the first coil arrangement and the second coil arrangement are each traversed by the hinge bolt through the openings.

32. The device as recited in claim 20, further comprising a compression device configured to press together the first housing part and the second housing part.

33. The device as recited in claim 32, wherein the compression device comprises at least one compression spring arrangement configured to act at least on a bottom of at least one of first housing part and the second housing part.
